(19) United States
(12) Patent Application Publication
(10) Pub. No.: US 2015/0084163 A1
(43) Pub. Date: Mar. 26, 2015

(54) EPITAXIAL SUBSTRATE, SEMICONDUCTOR DEVICE, AND METHOD FOR MANUFACTURING SEMICONDUCTOR DEVICE

(71) Applicants: SANKEN ELECTRIC CO., LTD., Niiza-shi, Saitama (JP); SHIN-ETSU HANDOTAI CO., LTD., Tokyo (JP)

(72) Inventors: Hiroshi Shikauchi, Niiza-shi (JP); Hirokazu Goto, Minato-ku (JP); Ken Sato, Miyoshi-machi (JP); Masaru Shinomiya, Annaka (JP); Keitaro Tsuchiya, Takasaki (JP); Kazunori Hagimoto, Takasaki (JP)

(21) Appl. No.: 14/397,779

(22) PCT Filed: Apr. 19, 2013
(86) PCT No.: PCT/JP2013/002646

§ 371 Date: Oct. 29, 2014

(30) Foreign Application Priority Data
May 11, 2012 (JP) 2012-109637

(51) Int. Cl. H01L 23/00; H01L 29/20; H01L 21/02

(52) U.S. Cl. CPC H01L 23/562; H01L 21/02381; H01L 21/0254; H01L 21/02458; H01L 29/2003
USPC 257/615; 438/478

(57) ABSTRACT

The present invention provides an epitaxial substrate including a silicon substrate containing oxygen atoms in concentrations of 4×10¹⁷ cm⁻³ or more and 6×10¹⁷ cm⁻³ or less and containing boron atoms in concentrations of 5×10¹⁸ cm⁻³ or more and 6×10¹⁹ cm⁻³ or less and a semiconductor layer that is placed on the silicon substrate and is made of a material having a thermal expansion coefficient different from the thermal expansion coefficient of the silicon substrate. As a result, the epitaxial substrate in which the occurrence of warpage caused by the stress between the silicon substrate and the semiconductor layer is suppressed is provided.

### BACKGROUND OF THE INVENTION

1. Field of the Invention

The present invention relates to an epitaxial substrate having an epitaxially-grown layer formed on a silicon substrate, a semiconductor device, and a method for manufacturing the semiconductor device.

2. Description of the Related Art

In a semiconductor device, an epitaxial substrate having a semiconductor layer which is formed on an inexpensive silicon substrate by epitaxial growth and is made of a material, such as a nitride semiconductor, which is different from the material of the silicon substrate, is used. However, due to a difference in lattice constant and a difference in thermal expansion coefficient between the silicon substrate and the semiconductor layer, great stress is produced between the silicon substrate and the semiconductor layer at the time of epitaxial growth of the semiconductor layer or when the temperature is reduced. By generation of such great stress, plastic deformation appears in the silicon substrate, thereby enormous warpage occurs. As a result, an epitaxial substrate that cannot be used in a semiconductor device is produced.

To avoid this problem, a method for suppressing the warpage of a silicon substrate by increasing the strength of the silicon substrate by adding boron (B) to the silicon substrate has been proposed (see, for example, Patent Literature 1).
Patent Literature 1: Japanese Patent No. 4519196

### SUMMARY OF THE INVENTION

It has been known that the strength of a silicon substrate can be increased by adding boron (B) to the silicon substrate. However, as for the silicon substrate to which boron has been added, an appropriate concentration of oxygen contained in the silicon substrate has not been well studied.

An object of the present invention is to provide an epitaxial substrate, a semiconductor device, and a method for manufacturing the semiconductor device in which the occurrence of warpage caused by the stress between a silicon substrate and a semiconductor layer is suppressed by defining the concentrations of oxygen atoms and boron atoms which are contained in the silicon substrate.

According to an aspect of the present invention, an epitaxial substrate including: a silicon substrate containing oxygen atoms in concentrations of 4×10¹⁷ cm⁻³ or more and 6×10¹⁷ cm⁻³ or less and containing boron atoms in concentrations of 5×10¹⁸ cm⁻³ or more and 6×10¹⁹ cm⁻³ or less; and a semiconductor layer that is placed on the silicon substrate and is made of a material having a thermal expansion coefficient different from the thermal expansion coefficient of the silicon substrate is provided.

According to another aspect of the present invention, a semiconductor device including: a silicon substrate containing oxygen atoms in concentrations of 4×10¹⁷ cm⁻³ or more and 6×10¹⁷ cm⁻³ or less and containing boron atoms in concentrations of 5×10¹⁸ cm⁻³ or more and 6×10¹⁹ cm⁻³ or less; a semiconductor layer that is placed on the silicon substrate and is made of a material having a thermal expansion coefficient different from the thermal expansion coefficient of the silicon substrate; and an electrode electrically connected to the semiconductor layer is provided.

According to still another aspect of the present invention, a method for manufacturing a semiconductor device, the method including: preparing a silicon substrate containing oxygen atoms in concentrations of 4×10¹⁷ cm⁻³ or more and 6×10¹⁷ cm⁻³ or less and containing boron atoms in concentrations of 5×10¹⁸ cm⁻³ or more and 6×10¹⁹ cm⁻³ or less; forming, on the silicon substrate by epitaxial growth method, a semiconductor layer made of a material having a thermal expansion coefficient different from the thermal expansion coefficient of the silicon substrate while heating the silicon substrate; and forming an electrode electrically connected to the semiconductor layer, is provided.

According to the present invention, it is possible to provide an epitaxial substrate, a semiconductor device, and a method for manufacturing the semiconductor device in which the occurrence of warpage caused by the stress between a silicon substrate and a semiconductor layer is suppressed,.

### BRIEF DESCRIPTION OF DRAWINGS

FIG. 1 is a schematic sectional view depicting the structure of an epitaxial substrate according to an embodiment of the present invention;

FIG. 2 is a graph depicting the relationship between the thermal expansion coefficient and the temperature of each material;

FIG. 3 is a schematic sectional view depicting the structure of a buffer layer of the epitaxial substrate according to the embodiment of the present invention; FIG. 3(a) depicting the structure of the buffer layer formed of two nitride semiconductor layer multi-layer films and FIG. 3(b) depicting the structure of an intermittent buffer layer;

FIG. 4 is a table depicting the relationship between the concentration of oxygen atoms contained in a silicon substrate and the yield of the silicon substrate;

FIG. 5 is a schematic sectional view depicting a structural example of a semiconductor device using the epitaxial substrate according to the embodiment of the present invention;

FIG. 6 is a schematic sectional view depicting another structural example of the semiconductor device using the epitaxial substrate according to the embodiment of the present invention;

FIG. 7 is a schematic sectional view depicting still another structural example of the semiconductor device using the epitaxial substrate according to the embodiment of the present invention; and

FIG. 8 is a schematic sectional view depicting further still another structural example of the semiconductor device using the epitaxial substrate according to the embodiment of the present invention.

### DETAILED DESCRIPTION OF THE PREFERRED EMBODIMENTS

Next, with reference to the drawings, an embodiment of the present invention will be described. In the following descriptions of the drawings, the same or similar numerals are attached to the same or similar portions. However, it should be understood that the drawings are schematic drawings and the relationship between the thickness and the planar dimensions, the proportion of the length of each portion to the lengths of other portions, and so forth are different from the actual relationship and proportion. Therefore, specific dimensions have to be judged based on the following descriptions. Moreover, it goes without saying that the drawings also include a portion whose relationship and proportion of dimensions in one drawing differ from those in another drawing.

Moreover, the embodiment described below depicts an example of a device and a method for embodying the technical idea of this invention, and the technical idea of this invention does not limit the shapes, structures, placement, and so forth of component elements to those described below. Various changes can be made to the embodiment of this invention in the scope of the claims.

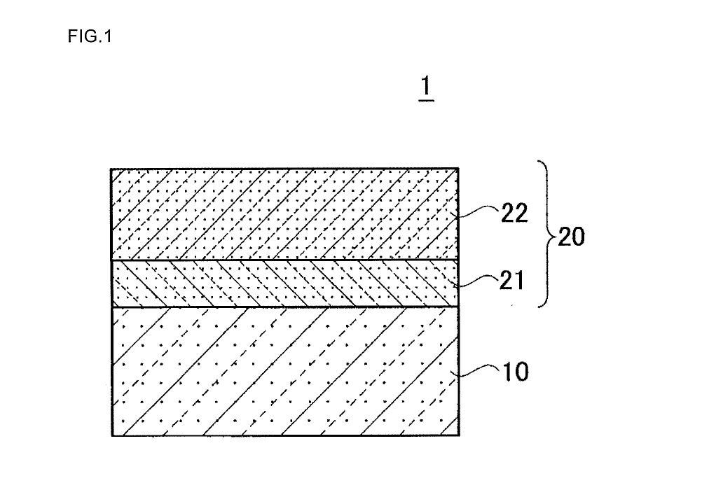

An epitaxial substrate 1 according to the embodiment of the present invention depicted in FIG. 1 includes a silicon substrate 10 containing oxygen (O) atoms in concentrations of 4×10¹⁷ cm⁻³ or more and 6×10¹⁷ cm⁻³ or less and containing boron (B) atoms in concentrations of 5×10¹⁸ cm⁻³ or more and 6×10¹⁹ cm⁻³ or less and a semiconductor layer 20 which is placed on the silicon substrate 10 and made of a material having a thermal expansion coefficient which is different from the thermal expansion coefficient of the silicon substrate 10.

The semiconductor layer 20 is an epitaxially-grown layer formed by epitaxial growth method. The material having a thermal expansion coefficient which is different from the thermal expansion coefficient of the silicon substrate 10 is a nitride semiconductor, group III-V compound semiconductors such as gallium arsenide (GaAs) and indium phosphide (InP), and group II-VI compound semiconductors such as silicon carbide (SiC), diamond, zinc oxide (ZnO), and zinc sulfide (ZnS). Hereinafter, a case where the semiconductor layer 20 is made of the nitride semiconductor will be described as an example.

The nitride semiconductor layer is formed on the silicon substrate 10 by metalorganic chemical vapor deposition (MOCVD) or the like. A typical nitride semiconductor is expressed as AlₓIn_{y}Ga_{1-x-y}N (0≦x≦1, 0≦y≦1, 0≦x+y≦1) and is gallium nitride (GaN), aluminum nitride (AlN), indium nitride (InN), and so forth.

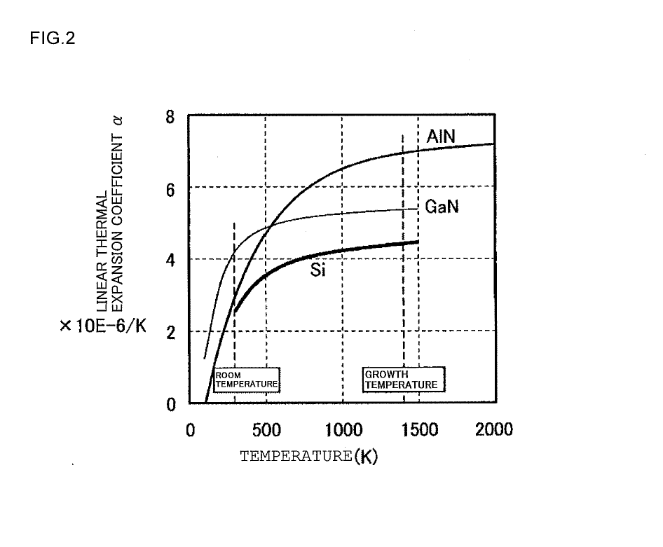

In FIG. 2, a graph of comparison among thermal expansion coefficients of materials is depicted. FIG. 2 depicts the relationship between the temperature and a linear thermal expansion coefficient α of each semiconductor material. At temperatures of 1000 K or more, the relationship among the thermal expansion coefficients of the materials is Si<GaN<AlN and the relationship among the lattice constants is AlN (a-axis)<GaN (a-axis)<Si ((111) plane). Since there are differences in lattice constant, thermal expansion coefficient, and so forth among silicon, AlN, and GaN, if, after setting the temperature of the silicon substrate 10 at a high temperature of 1000 K or more, for example, and stacking the nitride semiconductor on the silicon substrate 10 in such a way as to obtain lattice matching, the temperature of the silicon substrate 10 is reduced or heat treatment is performed on the semiconductor layer 20, stress is produced in the silicon substrate 10 and the semiconductor layer 20 thereby a crack and warpage of the substrate easily occur.

In the example depicted in FIG. 1, the semiconductor layer 20 is a stacked body of a buffer layer 21 and a functional layer 22. As the functional layer 22, various configurations are adopted depending on a semiconductor device that is produced by using the epitaxial substrate 1. The details of the functional layer 22 will be described later.

Since the thermal expansion coefficient of the silicon substrate 10 and the thermal expansion coefficient of the semiconductor layer 20 are different from each other, considerable strain energy is generated in the epitaxial substrate 1. The buffer layer 21 is placed between the silicon substrate 10 and the functional layer 22 and suppresses the occurrence of a crack, a reduction in crystal quality, and warpage of the substrate which are caused by the distortion in the functional layer 22.

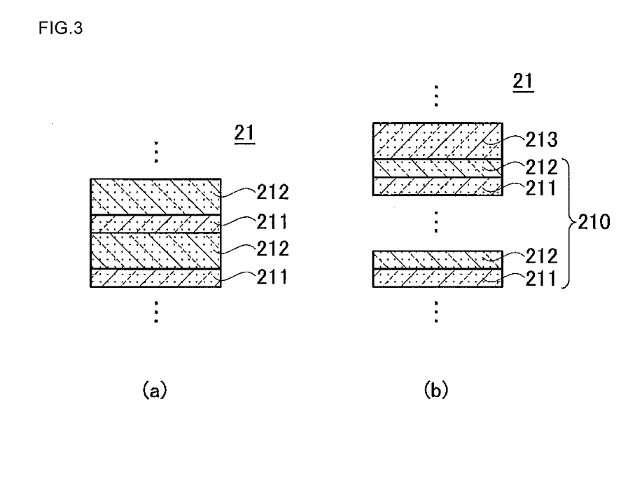

As the buffer layer 21, in general, a structure formed of a plurality of stacked nitride semiconductor layers whose lattice constants and thermal expansion coefficients are different from each other can be adopted. For example, as the buffer layer 21, a multi-layer film which is formed of a pair of stacked AlGaN layers having different composition ratios from each other, is used. Specifically, as depicted in FIG. 3(a), a multi-layer film, for example, which is formed of alternately stacked first nitride semiconductor layer 211 and second nitride semiconductor layer 212 is used. For example, the first nitride semiconductor layer 211 is an aluminum nitride (AlN) layer with a film thickness of about 5 nm, and the second nitride semiconductor layer 212 is a gallium nitride (GaN) layer with a film thickness of about 20 nm.

Alternatively, an “intermittent buffer structure” having a plurality of multi-layer films formed of a nitride semiconductor and a thick nitride semiconductor layer placed between the multi-layer films can be adopted as the buffer layer 21. As depicted in FIG. 3(b), for example, the buffer layer 21 having the intermittent buffer structure has a multi-layer film 210 formed of a plurality of stacked pairs of the first nitride semiconductor layer 211 and the second nitride semiconductor layer 212 whose compositions are different from each other and a third nitride semiconductor layer 213 which is stacked so as to be adjacent to the multi-layer film 210. By using a stacked body of the multi-layer film 210 and the third nitride semiconductor layer 213 as one unit and stacking a plurality of these units, the intermittent buffer structure is formed.

As a specific example of the intermittent buffer structure, a stacked body corresponding to one unit is formed by placing a GaN layer as the third nitride semiconductor layer 213 on the multi-layer film 210 formed of about ten stacked pairs in which each pair is formed of the alternately stacked AlN layer and GaN layer. By periodically repeating this stacked body structure, the buffer layer 21 having the intermittent buffer structure is formed. For example, the film thickness of the AlN film and the GaN film forming the multi-layer film 210 is about 5 nm, and the third nitride semiconductor layer 213 is a GaN layer with a film thickness of about 200 nm. By adopting the intermittent buffer structure, as compared to a structure in which the multi-layer film 210 formed of a pair of the AlGaN layer or the like is simply stacked, it is possible to further increase the film thickness of the buffer layer 21. This makes it possible to increase the breakdown voltage of the epitaxial substrate 1 in a vertical direction (a film thickness direction).

Hereinafter, the characteristics of the silicon substrate 10 according to the embodiment of the present invention will be described. The silicon substrate 10 is doped with a fixed concentration of boron atoms. By adding the boron atoms to the silicon substrate 10, it is possible to obtain the dislocation anchoring effect that the dislocation in the silicon substrate 10 is stopped by boron.

As a result of verification by the present inventors, it has been confirmed that, if the concentration of boron atoms contained in the silicon substrate 10 is lower than 5×10¹⁸ cm⁻³, the dislocation anchoring effect produced by boron is small. On the other hand, if the concentration of contained boron atoms is increased, the silicon substrate 10 becomes too hard, thereby a problem in a production process occurs. Specifically, it has been found out that, if the boron atom concentration of the silicon substrate 10 is higher than 6×10¹⁹ cm⁻³, it is difficult to produce a silicon substrate 10 having an appropriate thickness by slicing a silicon ingot and it is difficult to polish the silicon substrate 10.

Therefore, by adding boron atoms to the silicon substrate 10 in the range of atom concentrations from 5×10¹⁸ cm⁻³ or more and 6×10¹⁹ cm⁻³ or less, the dislocation anchoring effect by the boron atoms in the silicon substrate 10 operates effectively and no problem arises in a process step. That is, with the dislocation anchoring effect by the boron atoms, it is possible to increase the controllability of warpage of the silicon substrate 10.

Moreover, in order to prevent plastic deformation of the silicon substrate 10 at the time of growth of the semiconductor layer 20, crystal specifications that retard the progress of generation of oxide precipitate nuclei or crystal specifications with which generation of oxide precipitate nuclei hardly progresses as will be described below are adopted in the silicon substrate 10.

In general, at the time of production of a silicon ingot which is a material of a silicon substrate, oxygen atoms are taken into the silicon ingot and oxide precipitate nuclei are generated. Then, when, for example, a semiconductor layer is formed on the silicon substrate, an oxide (a precipitate) of SiO₂ is formed in the hot silicon substrate. Generally, as the concentration of oxygen atoms contained in the silicon substrate 10 is increased, dislocation anchoring occurs more easily, and the strength of the silicon substrate 10 is increased. However, if the above-described stress caused by a difference in thermal expansion coefficient between the semiconductor layer 20 and the silicon substrate 10 is produced around an oxide or punch-out dislocation by the oxide is generated, a shift (a slip) of a crystal axis or a defect occurs in the silicon substrate by small external stress, thereby causing warpage in the silicon substrate. Thus, in the silicon substrate 10 according to the embodiment of the present invention, by retarding the progress of generation of oxide precipitate nuclei or preventing the generation thereof, the formation of this oxide is suppressed. As a result, it is possible to reduce the warpage of the silicon substrate 10.

Specifically, the crystal specifications of the silicon substrate 10 containing boron atoms in the above-described concentration range are determined such that the concentration of oxygen atoms is 4×10¹⁷ cm⁻³ or more and 6×10¹⁷ cm⁻³ or less.

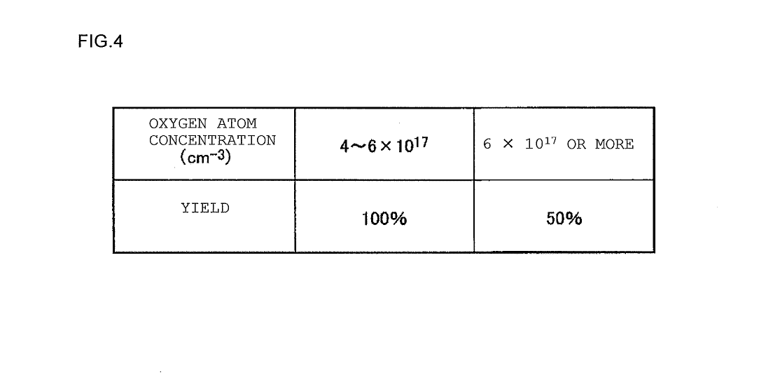

In FIG. 4, the relationship between the concentration of oxygen atoms contained in a silicon substrate whose boron atom concentration is 5 to 8×10¹⁸ cm⁻³ and the yield of the silicon substrate is depicted. In FIG. 4, the “amount of warpage” means a difference between a highest point and a lowest point of a principal surface of a silicon substrate (wafer), and, as the “yield”, the ratio of silicon substrates having warpage whose amount is within a tolerance that allows the silicon substrate to be used in a semiconductor device was adopted. As for the yield, a case where, in a silicon substrate with a diameter of 6 inches, the amount of warpage on the negative side (downward warpage in FIG. 4) was 100 μm or more was judged to be a defective.

As depicted in FIG. 4, in the silicon substrate whose oxygen atom concentration was 4 to 6×10¹⁷ cm⁻³, the yield was 100%. On the other hand, the yield of the silicon substrate whose oxygen atom concentration was 6×10¹⁷ cm⁻³ or more was 50% or less. Therefore, it is preferable that the concentration of oxygen atoms contained in the silicon substrate 10 is 6×10¹⁷ cm⁻³ or less.

On the other hand, when a silicon ingot which is the material of the silicon substrate 10 is produced by the CZ process, the productivity is decreased if the concentration of oxygen atoms contained in the silicon substrate 10 is less than 4×10¹⁷ cm⁻³. Because a lower limit of the oxygen atom concentration at which the oxygen atom concentration of the silicon ingot can be controlled accurately in a commonly-used silicon ingot production apparatus is about 4×10¹⁷ cm⁻³. Therefore, it is preferable that the concentration of oxygen atoms contained in the silicon substrate 10 is 4×10¹⁷ cm⁻³ or more.

As described above, by setting the concentration of oxygen atoms contained in the silicon substrate 10 within the range of 4×10¹⁷ cm⁻³ or more and 6×10¹⁷ cm⁻³ or less, the progress of generation of oxide precipitate nuclei in the silicon substrate 10 is suppressed. As a result, when the semiconductor layer 20 is formed by epitaxial growth method and the temperature of the silicon substrate 10 is reduced, it is possible to suppress the warpage of the silicon substrate 10. Incidentally, when the film thickness of the semiconductor layer 20 which is formed of the nitride semiconductor is 6 μm or more, suppression of plastic deformation of the silicon substrate 10 is particularly desired, and therefore it is preferable to use the present invention.

As explained above, according to the epitaxial substrate 1 according to the embodiment of the present invention, by controlling the concentrations of oxygen atoms and boron atoms which are contained in the silicon substrate 10 so as to be within predetermined ranges, it is possible to suppress warpage caused by the stress between the silicon substrate 10 and the semiconductor layer 20. As a result, in the epitaxial substrate 1 having a structure in which the semiconductor layer 20 whose thermal expansion coefficient is different from the thermal expansion coefficient of the silicon substrate 10 is stacked on the silicon substrate 10, the occurrence of a crack which is caused by the plastic deformation of the silicon substrate 10 in the semiconductor layer 20, is suppressed.

Hereinafter, a method for manufacturing the epitaxial substrate 1 will be explained. Incidentally, the method for manufacturing the epitaxial substrate 1 which will be described below is an example, and it goes without saying that the method can be implemented by various other production methods including modified example.

A silicon ingot is produced by the MCZ process or the like. At this time, a predetermined amount of boron is put into a quartz crucible containing polycrystal silicon. The amount of boron is adjusted such that the concentration of boron atoms contained in a silicon ingot to be produced becomes 5×10¹⁸ cm⁻³ or more and 6×10¹⁹ cm⁻³ or less.

Moreover, for example, by mixing a predetermined amount of oxygen atoms from the surface of the quartz crucible, the concentration of oxygen atoms contained in the silicon ingot is adjusted so as to be 4×10¹⁷ cm⁻³ or more and 6×10¹⁷ cm⁻³ or less.

By slicing the produced silicon ingot, a silicon substrate 10 having a desired thickness is obtained.

Incidentally, by measuring the resistivity of the silicon substrate 10, it is possible to confirm the boron atom concentration. For example, the boron atom concentration is converted from the resistivity by using an Irvin Curve, and the characteristics of the silicon substrate 10 are ensured. Alternatively, the boron atom concentration is confirm by secondary ion mass spectrometry (SIMS) or chemical analysis. The oxygen atom concentration of the silicon substrate 10 is measured by, for example, the infrared absorption method, gas fusion analysis method (GFA method), or the like.

In this manner, the silicon substrate 10 containing oxygen atoms in concentrations of 4×10¹⁷ cm⁻³ or more and 6×10¹⁷ cm⁻³ or less and containing boron atoms in concentrations of 5×10¹⁸ cm⁻³ or more and 6×10¹⁹ cm⁻³ or less is prepared.

Next, a semiconductor layer 20 which is made of a material having a thermal expansion coefficient which is different from the thermal expansion coefficient of the silicon substrate 10 is epitaxially grown on the silicon substrate 10 by MOCVD method or the like. Specifically, the silicon substrate 10 is stored in a film formation apparatus and a predetermined source gas is supplied to the inside of the film formation apparatus, thereby the semiconductor layer 20 is formed. A structure suitable as the buffer layer 21 is a structure in which an AlN layer and a GaN layer are alternately stacked. By sequentially stacking the buffer layer 21 and the functional layer 22 on the silicon substrate 10 heated to 900° C. or more, for example, 1350° C., the semiconductor layer 20 is formed.

For example, in a process in which the AlN layer is grown, a trimethylaluminum (TMA) gas which is an Al material and an ammonia (NH₃) gas which is a nitrogen material are supplied to the film formation apparatus. Moreover, in a process in which the AlGaN layer is grown, in addition to the TMA gas and the ammonia gas, a trimethylgallium (TMG) gas which is a Ga material is supplied to the film formation device. In a process in which the GaN layer is grown, the TMG gas and the ammonia gas are supplied to the film formation apparatus. In this way, the epitaxial substrate 1 depicted in FIG. 1 is completed.

Even when the silicon substrate 10 is heated to 900° C. or more, for example, in order to grow the semiconductor layer 20 epitaxially, by controlling the concentrations of oxygen atoms and boron atoms which are contained in the silicon substrate 10 so as to be within the above-described predetermined ranges, the occurrence of warpage caused by the stress between the silicon substrate 10 and the semiconductor layer 20 after the formation of the epitaxial substrate 1 is suppressed. As a result, it is possible to prevent an epitaxial substrate 1 that cannot be used for production of a semiconductor device due to significant warpage from being produced.

By adopting a semiconductor film having a predetermined structure as the functional layer 22 and placing an electrode that electrically connects to the functional layer 22 on the epitaxial substrate 1 by placing the electrode on the semiconductor layer 20, a semiconductor device that implements various functions is produced.

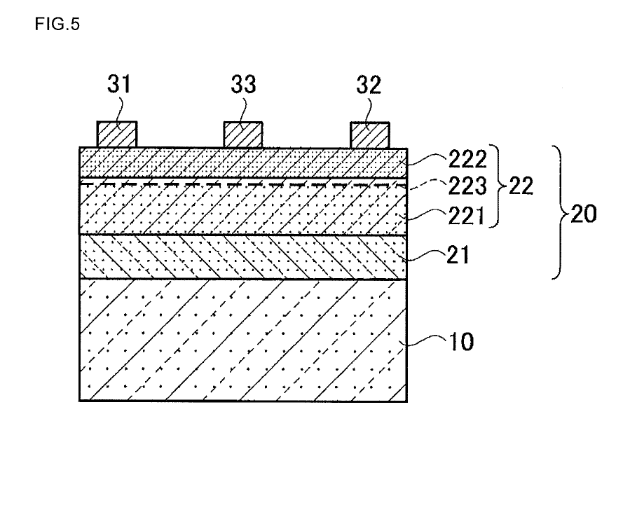

In FIG. 5, an example in which a high-electron-mobility transistor (HEMT) is produced by using the epitaxial substrate 1 is depicted. That is, a semiconductor device depicted in FIG. 5 has a functional layer 22 having a structure in which a carrier transit layer 221 and a carrier supply layer 222 forming a hetero junction with the carrier transit layer 221 are stacked. A hetero junction plane is formed at an interface between the carrier transit layer 221 and the carrier supply layer 222 which are formed of nitride semiconductors of which the band gap energy of one nitride semiconductor is different from the band gap energy of another, and a two-dimensional carrier gas layer 223 as a current path (a channel) is formed in the carrier transit layer 221 near the hetero junction plane. In order to generate the good two-dimensional carrier gas layer 223 and improve breakdown voltage, it is preferable that the film thickness of the semiconductor layer 20 which is formed of the nitride semiconductor is 6 μm or more and it is preferable that the film thickness of the carrier transit layer 221 in which the channel is formed is 3 μm or more.

The carrier transit layer 221 is formed, for example, by forming a non-doped GaN to which no impurities are added by MOCVD method or the like. Here, non-doped means that impurities are not added intentionally.

The carrier supply layer 222 placed on the carrier transit layer 221 is formed of a nitride semiconductor whose band gap is greater than the band gap of the carrier transit layer 221 and whose lattice constant is smaller than the lattice constant of the carrier transit layer 221. As the carrier supply layer 222, non-doped AlₓGa₁₋ₓN can be adopted.

The carrier supply layer 222 is formed on the carrier transit layer 221 by MOCVD method or the like. Since the carrier supply layer 222 and the carrier transit layer 221 have different lattice constants from each other, piezoelectric polarization due to lattice distortion occurs. Due to this piezoelectric polarization and spontaneous polarization of the crystal of the carrier supply layer 222, a high-density carrier is generated in the carrier transit layer 221 near the hetero junction, and the two-dimensional carrier gas layer 223 is formed.

As depicted in FIG. 5, on the functional layer 22, a source electrode 31, a drain electrode 32, and a gate electrode 33 are placed. The source electrode 31 and the drain electrode 32 are formed of metal that can form a low-resistance contact (an ohmic contact) with the functional layer 22. For example, aluminum (Al), titanium (Ti), and so forth can be adopted as the source electrode 31 and the drain electrode 32. Alternatively, the source electrode 31 and the drain electrode 32 are a stacked body of Ti and Al. As the gate electrode 33 placed between the source electrode 31 and the drain electrode 32, nickel gold (NiAu), for example, can be adopted.

In the above description, the example in which the semiconductor device using the epitaxial substrate 1 is the HEMT has been shown, but a transistor having another structure such as an insulated gate field-effect transistor (MISFET) or a vertical field-effect transistor (FET) may be formed by using the epitaxial substrate 1.

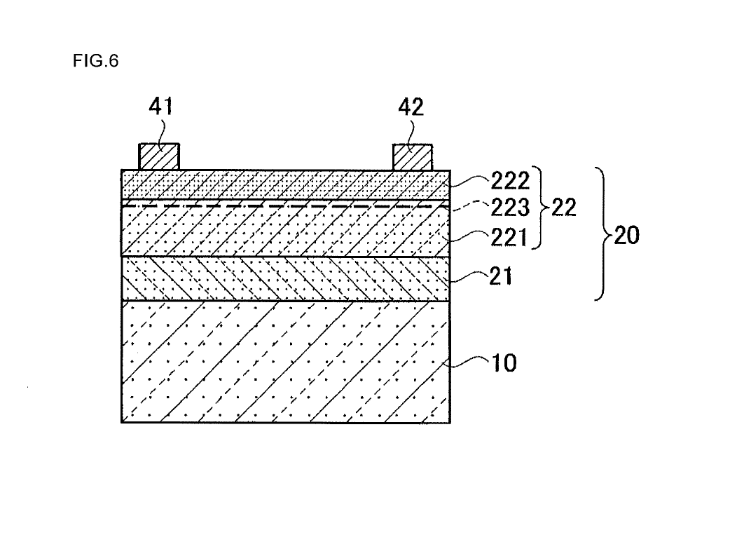

Moreover, in order to implement a Schottky barrier diode (SBD) by using the epitaxial substrate 1, a structure depicted in FIG. 6 can be adopted. That is, as is the case with the HEMT, a functional layer 22 is formed by using, for example, a carrier transit layer 221 formed of a GaN film and a carrier supply layer 222 formed of an AlGaN film. Then, an anode electrode 41 and a cathode electrode 42 are placed on the functional layer 22 so as to provide space between the anode electrode 41 and the cathode electrode 42. A Schottky junction is formed between the anode electrode 41 and the functional layer 22, and an ohmic junction is formed between the cathode electrode 42 and the functional layer 22. In the SBD depicted in FIG. 6, a current flows between the anode electrode 41 and the cathode electrode 42 via a two-dimensional carrier gas layer 223.

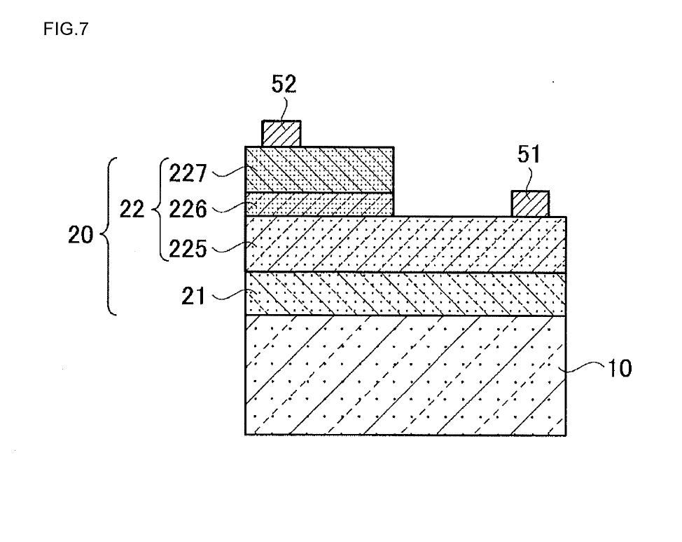

Moreover, a light-emitting device such as a light-emitting diode (LED) may be produced by using the epitaxial substrate 1. A light-emitting device depicted in FIG. 7 is an example in which a functional layer 22 having a double heterojunction structure formed of stacked n-type clad layer 225, active layer 226, and p-type clad layer 227 is placed on a buffer layer 21.

The n-type clad layer 225 is a GaN film or the like doped with n-type impurities, for example. As depicted in FIG. 7, an n-side electrode 51 is connected to the n-type clad layer 225, and an electron is supplied to the n-side electrode 51 from an external negative electric power supply of the light-emitting device. As a result, the electron is supplied to the active layer 226 from the n-type clad layer 225.

The p-type clad layer 227 is an AlGaN film doped with p-type impurities, for example. A p-side electrode 52 is connected to the p-type clad layer 227, and a positive hole (a hole) is supplied to the p-side electrode 52 from an external positive electric power supply of the light-emitting device. As a result, the positive hole is supplied to the active layer 226 from the p-type clad layer 227.

The active layer 226 is, for example, a non-doped InGaN film or a nitride semiconductor film doped with p-type or n-type conductivity type impurities. The electron supplied from the n-type clad layer 225 and the positive hole supplied from the p-type clad layer 227 recombine with each other in the active layer 226, thereby light is generated. Incidentally, as the active layer 226, a multiple quantum well (MQW) structure in which a barrier layer and a well layer whose band gap is smaller than the band gap of the barrier layer are alternately placed may be adopted. This MQW structure is a stacked structure of, for example, a nitride semiconductor layer formed of Alₓ₁Ga_{1-x1-y1}In_{y1}N (0.5<x1≦1, 0≦y1<1, 0<x1+y1≦1) and a nitride semiconductor layer formed of Alₓ₂Ga_{1-x2-y2}In_{y2}N (0.01<x2<0.5, 0≦y2<1, 0<x2+y2≦1).

Incidentally, for a semiconductor device using a p-type silicon substrate 10 doped with boron as part of the current path, the epitaxial substrate 1 according to the embodiment of the present invention is particularly effective. That is, by appropriately setting the oxygen atom concentration in the silicon substrate 10 that is inevitably doped with boron so as to provide the silicon substrate 10 with conductivity, it is possible to suppress the warpage of the silicon substrate 10. Thereby it is possible to reduce the electric resistance of the silicon substrate 10.

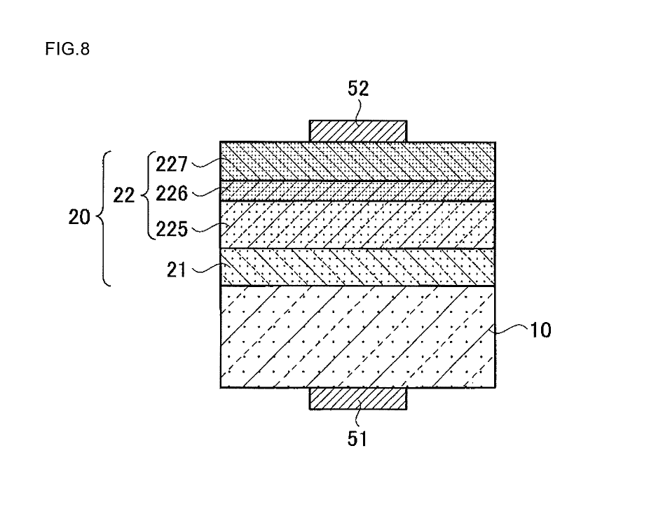

For example, as depicted in FIG. 8, by using the epitaxial substrate 1, a light-emitting device using the silicon substrate 10 as part of the current path can be produced. In the light-emitting device depicted in FIG. 8, the semiconductor layer 20 is placed on one principal surface of the silicon substrate 10 doped with boron and the n-side electrode 51 is placed on the other principal surface of the silicon substrate 10. The positive hole (the hole) is supplied to the p-type clad layer 227 from the p-side electrode 52 placed on the p-type clad layer 227 of the semiconductor layer 20. The electron is supplied to the n-type clad layer 225 from the n-side electrode 51 placed on the silicon substrate 10 via the silicon substrate 10 and the buffer layer 21.

As described above, by using the epitaxial substrate 1, it is possible to produce a semiconductor device having the semiconductor layer 20 in which the occurrence of a crack is suppressed and implementing various functions.

### OTHER EMBODIMENTS

As described above, the present invention has been described by using the embodiment, but it should not be understood that the description and drawings forming part of this disclosure limit this invention. A person skilled in the art can conceive of various alternative embodiments, examples, and operation techniques based on this disclosure.

For example, in the above description, an example in which the semiconductor layer 20 is a stacked body formed of the buffer layer 21 and the functional layer 22 has been described, but the semiconductor layer 20 may have a structure without the buffer layer 21. Moreover, a well known cap layer or spacer layer may be provided in or on the functional layer 22.

As described above, it goes without saying that the present invention includes various embodiments and so forth that have not been described above. Therefore, it is to be understood that the technical scope of the present invention is defined only by the appropriate subject matter according to the claims based on the above description.

1. An epitaxial substrate comprising:
a silicon substrate containing oxygen atoms in concentrations of 4×10¹⁷ cm⁻³ or more and 6×10¹⁷ cm⁻³ or less and containing boron atoms in concentrations of 5×10¹⁸ cm⁻³ or more and 6×10¹⁹ cm⁻³ or less; and
a semiconductor layer that is placed on the silicon substrate and is made of a material having a thermal expansion coefficient different from a thermal expansion coefficient of the silicon substrate.

2. The epitaxial substrate according to claim 1, wherein
the semiconductor layer is a stacked body of nitride semiconductor films.

3. A semiconductor device comprising:
a silicon substrate containing oxygen atoms in concentrations of 4×10¹⁷ cm⁻³ or more and 6×10¹⁷ cm⁻³ or less and containing boron atoms in concentrations of 5×10¹⁸ cm⁻³ or more and 6×10¹⁹ cm⁻³ or less;
a semiconductor layer that is placed on the silicon substrate and is made of a material having a thermal expansion coefficient different from a thermal expansion coefficient of the silicon substrate; and
an electrode electrically connected to the semiconductor layer.

4. The semiconductor device according to claim 3, wherein
the semiconductor layer is a stacked body of nitride semiconductor films.

5. A method for manufacturing a semiconductor device, comprising:
preparing a silicon substrate containing oxygen atoms in concentrations of 4×10¹⁷ cm⁻³ or more and 6×10¹⁷ cm⁻³ or less and containing boron atoms in concentrations of 5×10¹⁸ cm⁻³ or more and 6×10¹⁹ cm⁻³ or less;
forming, on the silicon substrate by epitaxial growth method, a semiconductor layer which is made of a material having a thermal expansion coefficient different from a thermal expansion coefficient of the silicon substrate while heating the silicon substrate; and
forming an electrode such that the electrode is electrically connected to the semiconductor layer.

6. The method for manufacturing a semiconductor device according to claim 5, wherein
as the semiconductor layer, a stacked body of nitride semiconductor films is formed.

7. The method for manufacturing a semiconductor device according to claim 5, wherein
in the forming the semiconductor layer, the silicon substrate is heated to 900° C. or more.

8. The method for manufacturing a semiconductor device according to claim 6, wherein
in the forming the semiconductor layer, the silicon substrate is heated to 900° C. or more.
